(19) United States
(12) Patent Application Publication
(10) Pub. No.: US 2013/0050942 A1
(43) Pub. Date: Feb. 28, 2013

(54) ELECTRONIC APPARATUS

(71) Applicant: Tatsunari Konishi, Kanagawa (JP)

(72) Inventor: Tatsunari Konishi, Kanagawa (JP)

(73) Assignee: SONY CORPORATION, Tokyo (JP)

(21) Appl. No.: 13/584,111

(22) Filed: Aug. 13, 2012

(30) Foreign Application Priority Data
Aug. 30, 2011 (JP) 2011-187929

(51) Int. Cl. H05K 7/20

(52) U.S. Cl. 361/692

(57) ABSTRACT

An electronic apparatus includes: an outer casing in which an air inflow hole allowing outside air to flow into internal space and a heat releasing hole releasing air temperature of which has been increased in the internal space to the outside are formed; a circuit substrate arranged in the internal space of the outer casing and on which electronic components to be heat sources at the time of driving are mounted; and a heat sink having an attachment base attached to the circuit substrate and plural fins protruding from the attachment base, wherein the outer casing is provided with fluid guide portions positioned opposite to the plural fins of the heat sink and guiding the air with increased temperature, the fluid guide portions are inclined in directions toward the heat releasing hole and the plural fins are inclined to directions toward the heat releasing hole.

### CROSS-REFERENCE TO RELATED APPLICATION

The present application claims priority from Japanese Patent Application No. JP 2011-187929 filed in the Japanese Patent Office on Aug. 30, 2011, the entire content of which is incorporated herein by reference.

### FIELD

The present disclosure relates to a technical field concerning an electronic apparatus. Particularly, the present disclosure relates to a technical field of improving heat release efficiency by inclining fluid guide portions provided at an outer casing and guiding air with increased temperature and fins of a heat sink.

### BACKGROUND

There are various electronic apparatuses provided with a circuit substrate in which a given wiring pattern is formed inside the outer casing such as a recording media recording/reproducing apparatus, an audio recording/reproducing apparatus, a cellular phone device, an image recording/reproducing apparatus, an imaging apparatus, an information processing apparatus and a network communication apparatus.

Electronic components having various functions are mounted on the circuit substrate, and these components generate heat at the time of driving. As the heat generated in the electronic components at the time of driving may affect operations in the electronic apparatuses, there exist electronic apparatuses provided with a heat sink for suppressing temperature increase due to generated heat in the circuit substrate (for example, refer to JP-A-5-160311 (Patent Document 1) and JP-A-6-21283 (Patent Document 2)).

The heat sink includes an attachment base attached on the circuit substrate and plural fins provided side by side on the attachment base. As plural fins are provided in the heat sink, a heat release area is increased and high heat release performance can be secured.

### SUMMARY

The electronic apparatus disclosed in Patent Document 1 has a structure in which convection is forcibly generated by using a cooling fan to release heat from the inside of the outer casing, which can secure high heat release efficiency. However, there is a problem that manufacturing costs are high as the cooling fan is necessary.

In the electronic apparatus disclosed in Patent Document 2, heat is released by using a heat sink having pin-type fins, however, there is no structure for effectively releasing heat released from the heat sink to the outside, and sufficiently high heat release efficiency is not secured.

In view of the above, it is desirable to improve heat release efficiency without increasing manufacturing costs.

An embodiment of the present disclosure is directed to an electronic apparatus including an outer casing in which an air inflow hole allowing outside air to flow into internal space and a heat releasing hole releasing air temperature of which has been increased in the internal space to the outside are formed, a circuit substrate arranged in the internal space of the outer casing and on which electronic components to be heat sources at the time of driving are mounted, and a heat sink having an attachment base attached to the circuit substrate and plural fins protruding from the attachment base, in which the outer casing is provided with fluid guide portions positioned opposite to the plural fins of the heat sink and guiding the air with increased temperature, the fluid guide portions are inclined in directions toward the heat releasing hole and the plural fins are inclined to directions toward the heat releasing hole.

Accordingly, the air flowing into the inside of the outer casing from the air inflow hole and the temperature of which has been increased is guided by the fluid guide portions toward the heat release hole, and the air temperature of which has been increased due to heat released from the fins are allowed to flow along the inclination of the fins toward the heat release hole.

In the electronic apparatus of the embodiment of the present disclosure, it is preferable that the outer casing includes a case portion having an outer peripheral surface portion, a top surface portion attached to the outer peripheral surface portion from one opening side of the outer peripheral surface portion and a bottom surface portion attached to the outer peripheral surface portion from the other opening side of the outer peripheral surface portion and that a gap is formed between the outer peripheral surface portion and the top surface portion, which is used as the heat releasing hole.

As the gap is formed between the outer peripheral surface portion and the top surface portion which is used as the heat releasing hole, the air temperature of which has been increased inside the outer casing is released from the gap between the outer peripheral surface portion and the top surface portion.

In the electronic apparatus of the embodiment of the present disclosure, it is preferable that the outer casing includes a case portion having an outer peripheral surface portion, a top surface portion attached to the outer peripheral surface portion from one opening side of the outer peripheral surface portion and a bottom surface portion attached to the outer peripheral surface portion from the other opening side of the outer peripheral surface portion and that a gap is formed between the outer peripheral surface portion and the bottom surface portion, which is used as the air inflow hole.

As the gap is formed between the outer peripheral surface portion and the bottom surface portion which is used as the air inflow hole, outside air flows inside the outer casing from the gap between the outer peripheral surface portion and the bottom surface portion.

In the electronic apparatus of the embodiment of the present disclosure, it is preferable that the heat releasing hole is formed in circumference between the outer peripheral surface portion and the top surface portion.

As the heat releasing hole is formed in circumference between the outer peripheral surface portion and the top surface portion, the amount of releasing air from the inside of the outer casing is increased.

In the electronic apparatus of the embodiment of the present disclosure, it is preferable that the air inflow hole is formed in circumference between the outer peripheral surface portion and the bottom surface portion.

As the air inflow hole is formed in circumference between the outer peripheral surface portion and the bottom surface portion, the amount of taking air inside the outer casing is increased.

In the electronic apparatus of the embodiment of the present disclosure, it is preferable that a surface in an outer peripheral portion of the top surface portion positioned opposite to the outer peripheral surface portion is formed as an inclined surface to be apart from the bottom surface portion as extending to an outer periphery in the above electronic apparatus.

As the surface in the outer peripheral portion of the top surface portion positioned opposite to the outer peripheral surface portion is formed as the inclined surface to be apart from the bottom surface portion as extending to the outer periphery, the air temperature of which has been increased and flowing inside the outer casing is allowed to flow along the inclined surface.

In the electronic apparatus of the embodiment of the present disclosure, it is preferable that a surface of the outer peripheral surface portion opposite to the top surface portion is formed as an inclined surface inclined in a direction along the inclined surface of the top surface portion in the above electronic apparatus.

As the surface of the outer peripheral surface portion opposite to the top surface portion is formed as the inclined surface inclined in the direction along the inclined surface of the top surface portion, the air temperature of which has been increased and flowing inside the outer casing is allowed to flow along the inclined surface.

In the electronic apparatus of the embodiment of the present disclosure, it is preferable that a surface in an outer peripheral portion of the bottom surface portion positioned opposite to the outer peripheral surface portion is formed as an inclined surface to be apart from the top surface portion as extending to an outer periphery.

As the surface in the outer peripheral portion of the bottom surface portion positioned opposite to the outer peripheral surface portion is formed as the inclined surface to be apart from the top surface portion as extending to the outer periphery, the air flowing toward the inside of the outer casing is allowed to flow along the inclined surface.

In the electronic apparatus of the embodiment of the present disclosure, it is preferable that a surface of the outer peripheral surface portion opposite to the bottom surface portion is formed as an inclined surface inclined in a direction along the inclined surface of the bottom surface portion.

As the surface of the outer peripheral surface portion opposite to the bottom surface portion is formed as the inclined surface inclined in a direction along the inclined surface of the bottom surface portion, the air flowing toward the inside of the outer casing is allowed to flow along the inclined surface.

In the electronic apparatus of the embodiment of the present disclosure, it is preferable that the outer casing is provided with guide wall portions guiding air flowing from the air inflow hole to directions toward the heat sink.

As the outer casing is provided with guide wall portions guiding air flowing from the air inflow hole to directions toward the heat sink, the amount of air flowing toward the heat sink is increased.

In the electronic apparatus of the embodiment of the present disclosure, it is preferable that the outer casing has a case portion having an outer peripheral surface portion, a top surface portion attached to the outer peripheral surface portion from one opening side of the outer peripheral surface portion and a bottom surface portion attached to the outer peripheral surface portion from the other opening side of the outer peripheral surface portion, and that the outer casing is provided with protruding portions having the guide wall portions and protruding from an inner surface of the outer peripheral surface portion.

As the outer casing is provided with protruding portions having the guide wall portions and protruding from the inner surface of the outer peripheral surface portion, the case portion is reinforced.

In the electronic apparatus of the embodiment of the present disclosure, it is preferable that an inclined angle of the plural fins of the heat sink is increased as coming close to the outer peripheral surface portion by using the center of the attachment base as a reference.

As the inclined angle of the plural fins of the heat sink is increased as coming close to the outer peripheral surface portion by using the center of the attachment base as a reference, intervals between fins become wider as the fins draw away from the attachment base.

In the electronic apparatus of the embodiment of the present disclosure, it is preferable that air flow holes allowing the air with increased temperature to flow are formed in at least one of the plural fins of the heat sink.

As the air flow holes allowing the air with increased temperature to flow are formed in at least one of the plural fins of the heat sink, flowability of the air with increased temperature between the fins is increased.

In the electronic apparatus of the embodiment of the present disclosure, it is preferable that air flow holes allowing the air with increased temperature to flow are formed in the attachment base of the heat sink.

As the air flow holes allowing the air with increased temperature to flow are formed in the attachment base of the heat sink, flowability of the air with increased temperature between the fins is increased.

The electronic apparatus according to the embodiment of the present disclosure includes the outer casing in which the air inflow hole allowing outside air to flow into internal space and the heat releasing hole releasing air temperature of which has been increased in the internal space to the outside are formed, the circuit substrate arranged in the internal space of the outer casing and on which electronic components to be heat sources at the time of driving are mounted, and the heat sink having an attachment base attached to the circuit substrate and plural fins protruding from the attachment base, in which the outer casing is provided with fluid guide portions positioned opposite to the plural fins of the heat sink and guiding the air with increased temperature, the fluid guide portions are inclined in directions toward the heat releasing hole and the plural fins are inclined to directions toward the heat releasing hole.

Accordingly, the heat released from the heat sink can be efficiently released from the outer casing to the outside without using a member for forcibly generating convection such as a cooling fan, which can improve heat release efficiency without increasing manufacturing costs.

In one configuration according to the embodiment of the present disclosure, the outer casing includes the case portion having the outer peripheral surface portion, the top surface portion attached to the outer peripheral surface portion from one opening side of the outer peripheral surface portion and the bottom surface portion attached to the outer peripheral surface portion from the other opening side of the outer peripheral surface portion, and the gap is formed between the outer peripheral surface portion and the top surface portion, which is used as the heat releasing hole.

Accordingly, it is not necessary to form plural heat releasing holes in the top surface portion or the case portion, and heat releasing performance can be increased by increasing the amount of releasing air from the inside of the outer casing while realizing simplification in structure of the top surface portion and the case portion.

In one configuration according to the embodiment of the present disclosure, the outer casing includes the case portion having the outer peripheral surface portion, the top surface portion attached to the outer peripheral surface portion from one opening side of the outer peripheral surface portion and the bottom surface portion attached to the outer peripheral surface portion from the other opening side of the outer peripheral surface portion, and the gap is formed between the outer peripheral surface portion and the bottom surface portion, which is used as the air inflow hole.

Accordingly, it is not necessary to form plural air inflow holes in the bottom surface portion or the case portion, and heat releasing performance can be increased by increasing the amount of taking air inside the outer casing while realizing simplification in structure of the bottom surface portion and the case portion.

In one configuration according to the embodiment of the present disclosure, the heat releasing hole is formed in circumference between the outer peripheral surface portion and the top surface portion.

Accordingly, the amount of releasing air from the inside of the outer casing is increased, which can improve heat release efficiency for the amount.

In one configuration according to the embodiment of the present disclosure, the air inflow hole is formed in circumference between the outer peripheral surface portion and the bottom surface portion.

Accordingly, the amount of taking air inside the outer casing is increased, which can improve heat release efficiency for the amount.

In one configuration according to the embodiment of the present disclosure, the surface in an outer peripheral portion of the top surface portion positioned opposite to the outer peripheral surface portion is formed as an inclined surface to be apart from the bottom surface portion as extending to an outer periphery.

Accordingly, the air temperature of which has been increased and flowing inside the outer casing flows along the inclined surface smoothly, which increases flowability of air to be released outside and improves heat release efficiency.

In one configuration according to the embodiment of the present disclosure, the surface of the outer peripheral surface portion opposite to the top surface portion is formed as the inclined surface inclined in the direction along the inclined surface of the top surface portion.

Accordingly, the air temperature of which has been increased and flowing inside the outer casing flows along the inclined surface smoothly, which increases flowability of air to be released outside and improves heat release efficiency.

In one configuration according to the embodiment of the present disclosure, the surface in the outer peripheral portion of the bottom surface portion positioned opposite to the outer peripheral surface portion is formed as the inclined surface to be apart from the top surface portion as extending to the outer periphery.

Accordingly, the air flowing toward the inside of the outer casing flows along the inclined surface smoothly, which increases flowability of air flowing to the inside of the outer casing and which improves heat release efficiency.

In one configuration according to the embodiment of the present disclosure, the surface of the outer peripheral surface portion opposite to the bottom surface portion is formed as the inclined surface inclined in the direction along the inclined surface of the bottom surface portion.

Accordingly, the air flowing toward the inside of the outer casing flows along the inclined surface smoothly, which increases flowability of air flowing to the inside of the outer casing and which improves heat release efficiency.

In one configuration according to the embodiment of the present disclosure, the outer casing is provided with guide wall portions guiding air flowing from the air inflow hole to directions toward the heat sink.

Accordingly, the amount of air flowing toward the heat sink is increased and heat release efficiency can be improved.

In one configuration according to the embodiment of the present disclosure, the outer casing has the case portion having the outer peripheral surface portion, the top surface portion attached to the outer peripheral surface portion from one opening side of the outer peripheral surface portion and the bottom surface portion attached to the outer peripheral surface portion from the other opening side of the outer peripheral surface portion, and the outer casing is provided with protruding portions having the guide wall portions and protruding from an inner surface of the outer peripheral surface portion.

Accordingly, the case portion is reinforced to thereby increase the stiffness of the case portion in addition to the improvement of heat release performance.

In one configuration according to the embodiment of the present disclosure, the inclined angle of the plural fins of the heat sink is increased as coming close to the outer peripheral surface portion by using the center of the attachment base as a reference.

Accordingly, intervals between adjacent fins become wider as the fins draw away from the attachment base and flowability of air with increased temperature between the fins is increased, which improves heat release efficiency for the increase.

In one configuration according to the embodiment of the present disclosure, the air flow holes allowing the air with increased temperature to flow are formed in at least one of the plural fins of the heat sink.

Accordingly, flowability of air with increased temperature between the fins is further increased, which can further improve heat release efficiency.

In one configuration according to the embodiment of the present disclosure, the air flow holes allowing the air with increased temperature to flow are formed in the attachment base of the heat sink.

Accordingly, flowability of air with increased temperature between the fins is further increased, which can further improve heat release efficiency.

### BRIEF DESCRIPTION OF THE DRAWINGS

FIG. 1 shows one embodiment of the present disclosure together with FIG. 2 to FIG. 18, and is a perspective view of an electronic apparatus;

FIG. 2 is an exploded perspective view of the electronic apparatus;

FIG. 3 is a cross-sectional view of the electronic apparatus;

FIG. 4 is a bottom view of a top surface portion;

FIG. 5 is a cross-sectional view taken along the line V-V of FIG. 4;

FIG. 6 is a bottom view of a case portion;

FIG. 7 is a cross-sectional view taken along the line VII-VII of FIG. 6;

FIG. 8 is a cross-sectional view taken along the line VIII-VIII of FIG. 6,

FIG. 9 is a cross-sectional view taken along the line IX-IX of FIG. 6;

FIG. 10 is a plan view of the bottom surface portion;

FIG. 11 is an enlarged perspective view of a heat sink;

FIG. 12 is a cross-sectional view showing flow paths of air;

FIG. 13 is an enlarged perspective view of a heat sink in which air flow holes are formed;

FIG. 14 is a cross-sectional view of an electronic apparatus showing an example of arranging a heat sink provided with two fins;

FIG. 15 shows an electronic apparatus used for measurement concerning heat release effects of the heat sink and fluid guide portions together with FIG. 16 to FIG. 18, which is a schematic view showing an electronic apparatus not having fluid guide portions and applying a heat sink having inclined fins;

FIG. 16 is a schematic view showing an electronic apparatus not having fluid guide portions and applying a heat sink having fins not being inclined;

FIG. 17 is a schematic view showing an electronic apparatus having fluid guide portions and using a heat sink having inclined fins; and

FIG. 18 is a schematic view showing an electronic apparatus having fluid guide portions and using a heat sink having fins not being inclined.

### DETAILED DESCRIPTION

Hereinafter, embodiments of the present disclosure will be explained with reference to the attached drawings.

In the best mode shown below, an electronic apparatus according to an embodiment of the present disclosure is applied to a network communication apparatus having a communication function of outputting images and video acquired by communication to a display device such as a television receiver and displaying them on the display device.

The application range of the electronic apparatus according to the embodiment of the present disclosure is not limited to the network communication apparatus. The electronic apparatus according to the embodiment of the present disclosure can be widely applied to other various electronic apparatuses, for example, a recording/reproducing apparatus for images and video, an audio recording/reproducing apparatus, an imaging apparatus and information processing apparatuses such as a personal computer or a PDA (Personal Digital Assistant).

In the following explanation, directions of front, back, up, down, right and left are indicated by determining a direction in which a circuit substrate arranged inside an outer casing faces is an up-and-down direction.

The directions of front, back, up, down, right and left shown below are used for convenience of explanation, and directions are not limited to these directions when carrying out the present disclosure.

### [Structure of Electronic Apparatus]

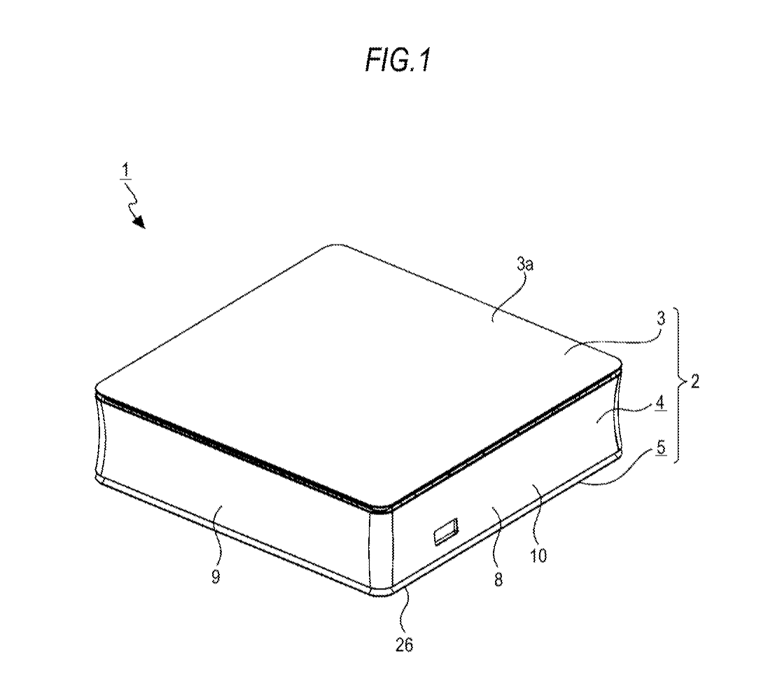

An electronic apparatus (network communication apparatus) 1 is configured by arranging necessary respective portions in an outer casing 2, in which the outer casing 2 includes a top surface portion 3, a case portion 4 and a bottom surface portion 5 which are made of a resin material (see FIG. 1 to FIG. 3).

The top surface portion 3 is formed to be an approximately rectangular plate shape facing the up and down direction, in which an upper surface 3a is formed in a flat surface.

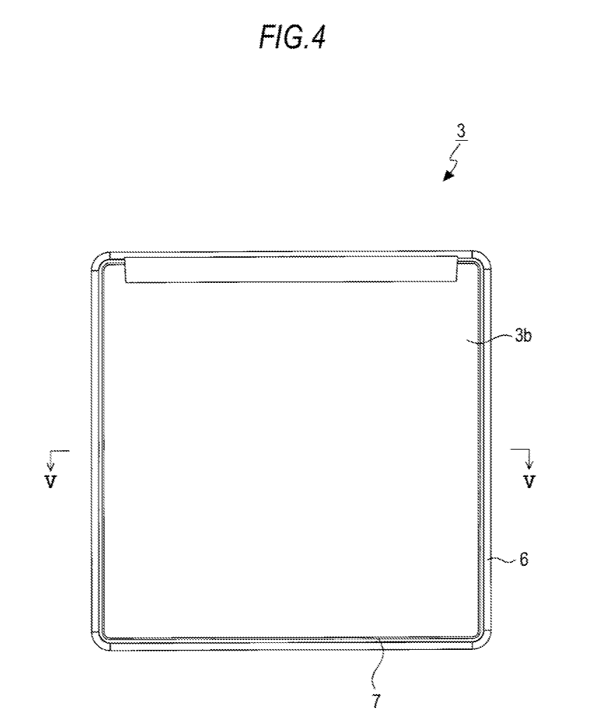

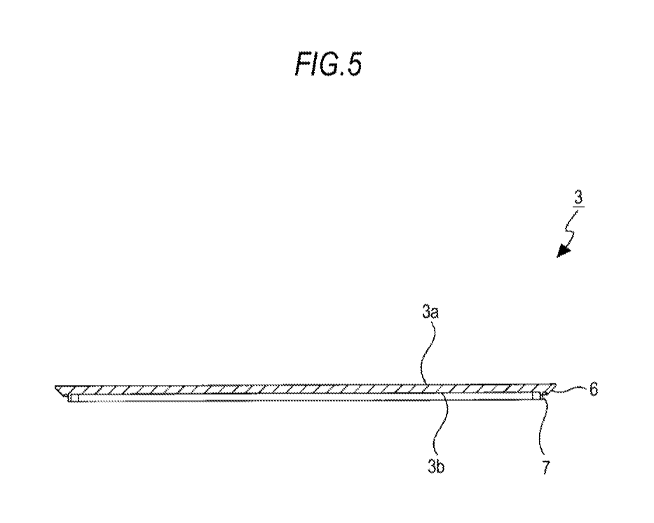

An outer peripheral portion of a lower surface 3b of the top surface portion 3 is formed as an inclined surface 6 which is displaced upward as extending outward (see FIG. 4 and FIG. 5). A ridge portion 7 is provided at positions along an outer periphery of the lower surface 3b of the top surface portion 3 except part thereof. The ridge portion 7 is provided so as to protrude downward from the lower surface 3b and extend in a circumferential direction.

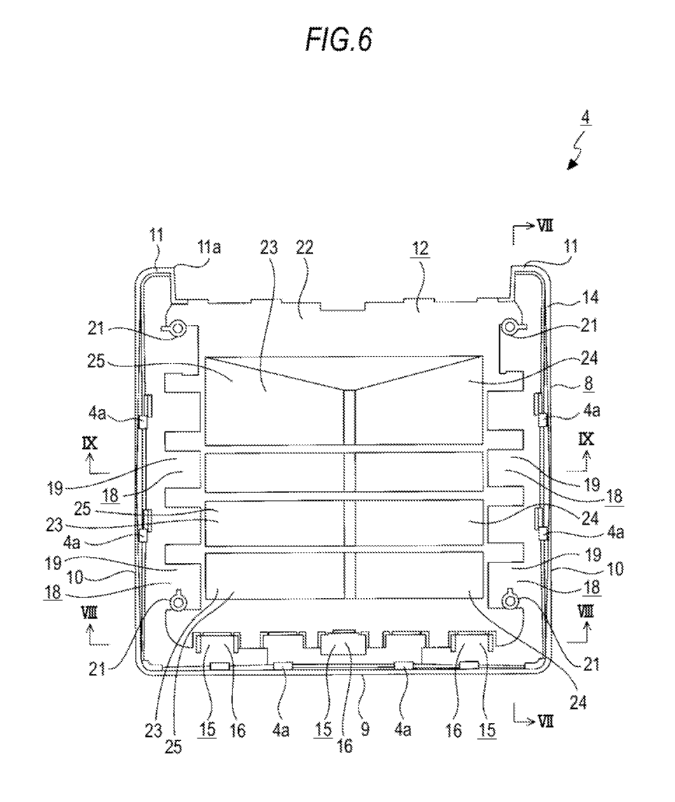

The case portion 4 is configured by integrally forming a frame-shaped outer peripheral surface portion 8 and respective portions provided inside the outer peripheral surface portion 8 (see FIG. 6 to FIG. 9). The outer peripheral surface portion 8 includes a front surface portion 9, a pair of side surface portions 10, 10 and protruding surface portions 11, 11 protruding in directions coming close to each other from rear edges of the pair of side surface portions 10, 10. A portion between the protruding surface portions 11, 11 is formed as an opening 11a. Respective outer surfaces of the front surface portion 9, the side surface portions 10, 10 and the protruding surface portions 11, 11 are respectively formed to be curved surfaces which are gently curved inward.

A connection surface portion 12 continuously formed from respective upper edge portions the front surface portion 9, the side surface portions 10, 10 and the protruding surface portions 11, 11 is provided in the case portion 4.

Locking concave portions 4a, 4a, . . . are provided on an inner surface side at a bottom edge portion of the case portion 4. The locking concave portions 4a, 4a, . . . are provided on the front surface portion 9 and the side surface portions 10, 10, which are positioned in the circumference direction apart from one another.

An inclined surface 13 displaced upward as extending outward is formed on an upper edge portion of the outer peripheral surface portion 8 and an inclined surface 14 displaced downward as extending outward is formed on a bottom edge portion of the outer peripheral surface portion 8.

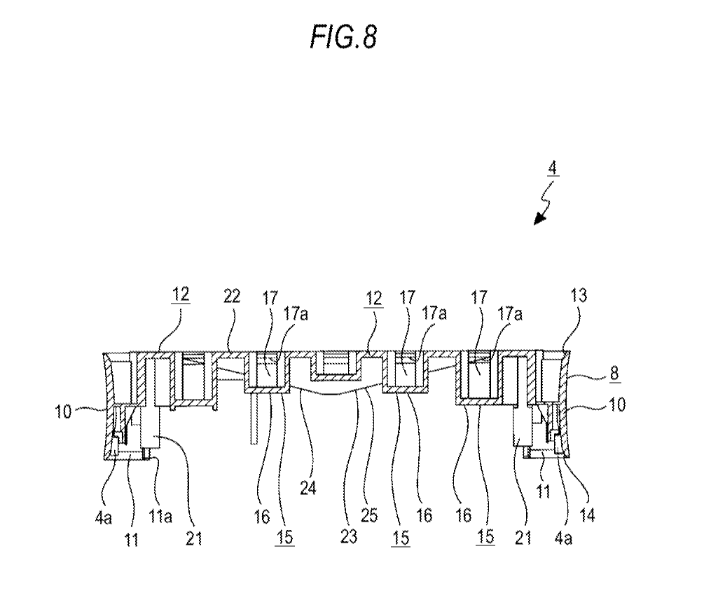

Protruding portions 15, 15, . . . are continuously provided from an inner surface of the front surface portion 9 so as to be apart from one another in a right and left direction in the case portion 4 (see FIG. 6 go FIG. 8). The protruding portions 15, 15, . . . are continuously provided on the upper half portion of the front surface portion 9, having first guide wall portions 16 protruding backward from the front surface portion 9 and facing up and down directions and second guide wall portions 17 protruding upward from tip portions of the first guide wall portions 16 and facing front and back directions.

Upper edge portions of the second guide wall portions 17 are connected to the connection surface portion 12. Releasing holes 17a are formed on portions on the upper edge side of the second guide wall portions 17.

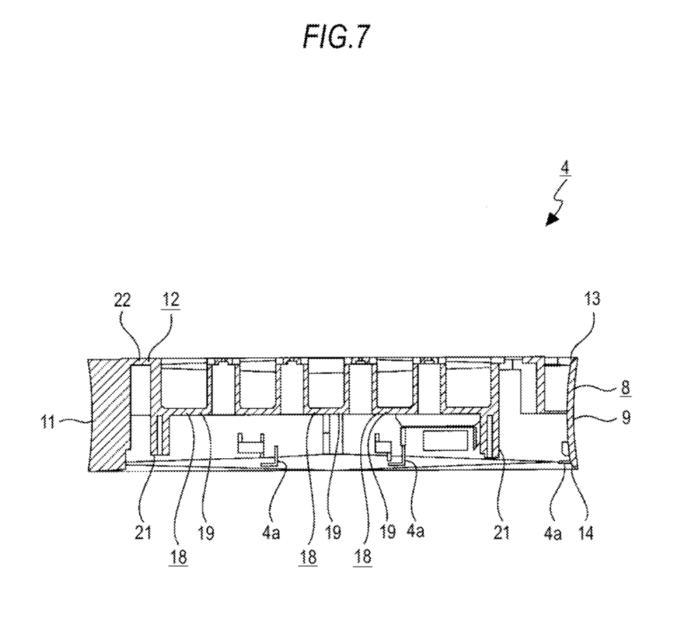

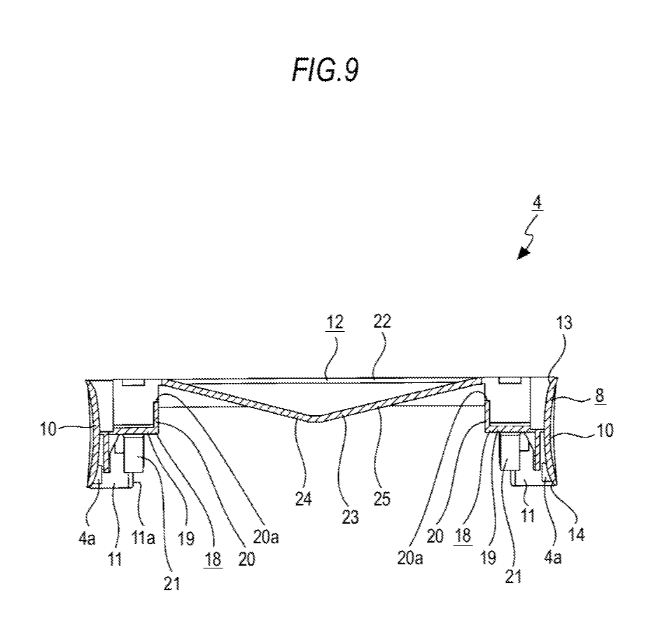

Protruding portions 18, 18, are continuously provided on inner surfaces of the side surface portions 10, 10 so as to be apart from one another in the front and back direction respectively in the case portion 4 (see FIG. 6, FIG. 7 and FIG. 9). The protruding portions 18, 18, . . . are continuously provided on the upper half portion of the side surface portions 10, having first guide wall portions 19 protruding in a left direction or a right direction from the side surface portions 10 and facing up and down directions and second guide wall portions 20 protruding upward from tip portions of the first guide wall portions 19 and facing right and left directions.

Upper edge portions of the second guide wall portions 20 are connected to the connection surface portion 12. Releasing holes 20a are formed on portions on the upper edge side of the second guide wall portions 20.

Connection shaft portions 21, 21, . . . protruding downward respectively are provided from four protruding portions 18, 18, . . . positioned apart from one another in front, back, right and left directions in the protruding portions 18, 18, . . . (see FIG. 6 to FIG. 9).

The connection surface portion 12 of the case portion 4 includes a plane portion 22 formed to be a flat plate shape facing the up and down directions and fluid guide portions 23, 23, . . . protruding downward (see FIG. 6, FIG. 8 and FIG. 9). The fluid guide portions 23, 23, . . . are provided apart from one another in the front and back direction, which are positioned between the protruding portions 18, 18, . . . positioned on the left side and the protruding portions 18, 18, . . . positioned on the right side.

Each fluid guide portion 23 includes a first guide surface portion 24 inclined so as to be displaced upward as extending in the left direction and a second guide surface portion 25 inclined so as to be displaced upward as extending in the right direction. A right edge of the first guide surface portion 24 and a left edge of the second guide surface portion 25 are connected at the center of the connection surface portion 12 in the right and left direction.

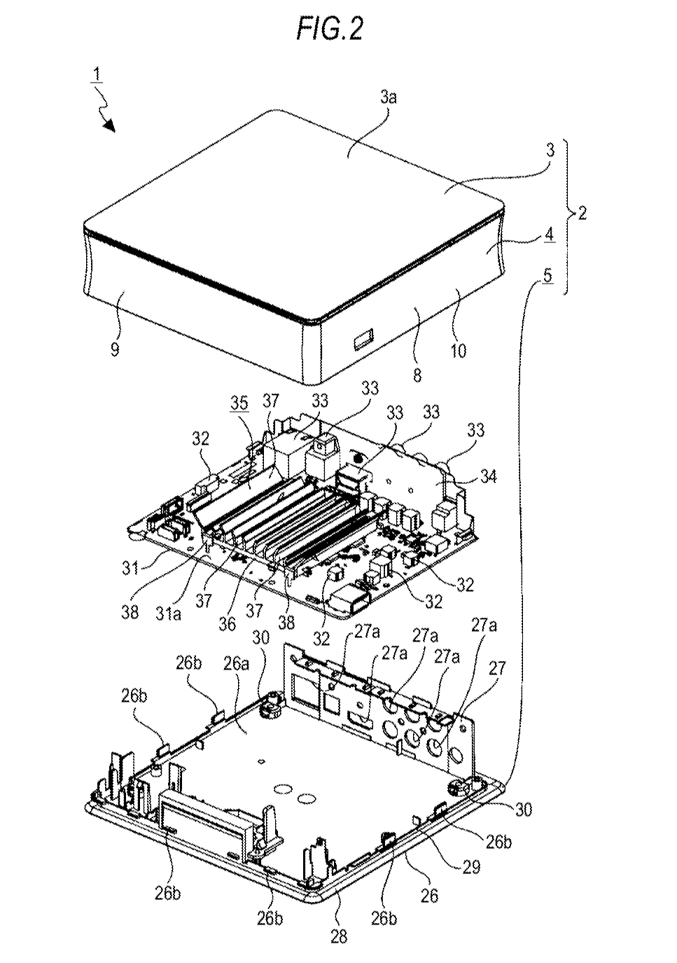

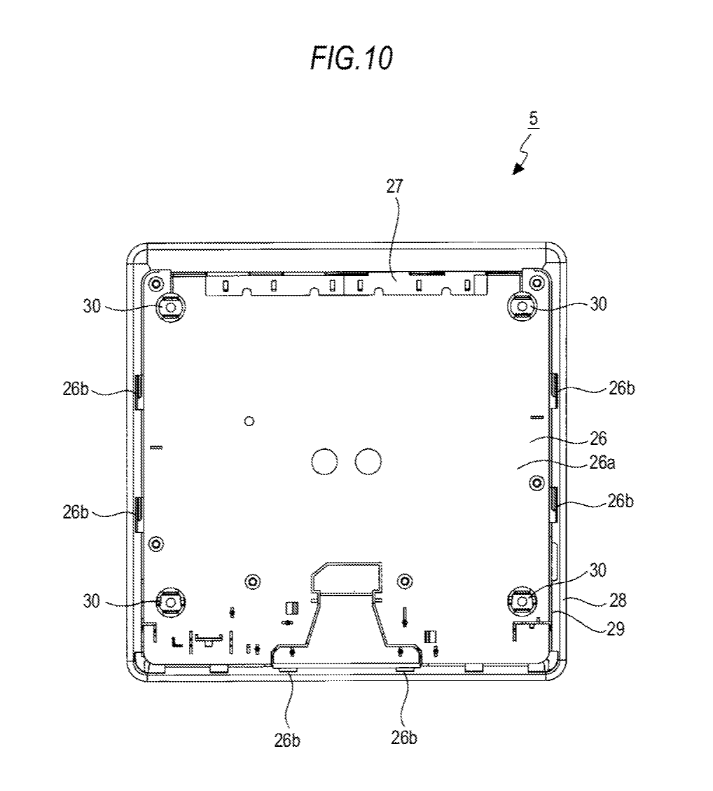

The bottom surface portion 5 includes a base plate portion 26 formed to be an approximately rectangular plate shape facing the up and down directions and a support wall portion 27 protruding upward from a rear end portion of the base plate portion 26 (see FIG. 2 and FIG. 10).

An outer peripheral portion of an upper surface 26a of the base plate portion 26 is formed as an inclined surface 28 which is displaced downward as extending outward. A ridge portion 29 is provided at positions along an outer periphery of the upper surface 26a of the base plate portion 26 except part thereof. The ridge portion 29 is provided so as to protrude upward from the upper surface 26a and extend in the circumferential direction.

Locking protrusions 26b, 26b, . . . are provided at portions other than the rear end portion of the outer peripheral portion of the base plate portion 26, and the locking protrusions 26b, 26b, . . . are positioned apart from one another in the circumferential direction.

Connection protrusions 30, 30, . . . are provided apart from one another in the front, back, right and left directions on the upper surface 26a of the base plate portion 26.

The support wall portion 27 is formed to have an approximately landscape rectangular shape, including plural arrangement holes 27a, 27a, . . . .

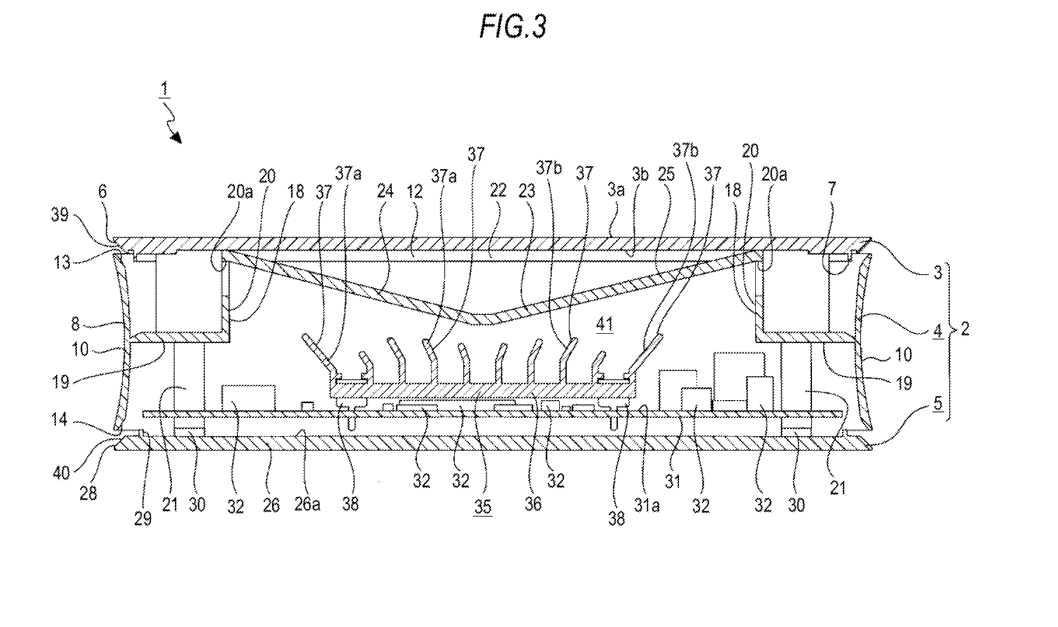

A circuit substrate 31 is attached on the upper surface 26a of the base plate portion 26 of the bottom surface portion 5 (see FIG. 2 and FIG. 3). Plural electronic components 32, 32, . . . respectively having given functions are mounted on the circuit substrate 31. The electronic components 32, 32, . . . are heat sources generating heat at the time of driving.

Connectors 33, 33, . . . are mounted on a rear end portion on an upper surface of the circuit substrate 31. In the rear end portion of the circuit substrate 31, a support plate 34 is attached so as to protrude upward from the circuit substrate 31, and the connectors 33, 33, . . . are supported in the support plate 34. The connectors 33, 33, . . . are arranged in the arrangement holes 27a, 27a, . . . formed in the support wall portion 27.

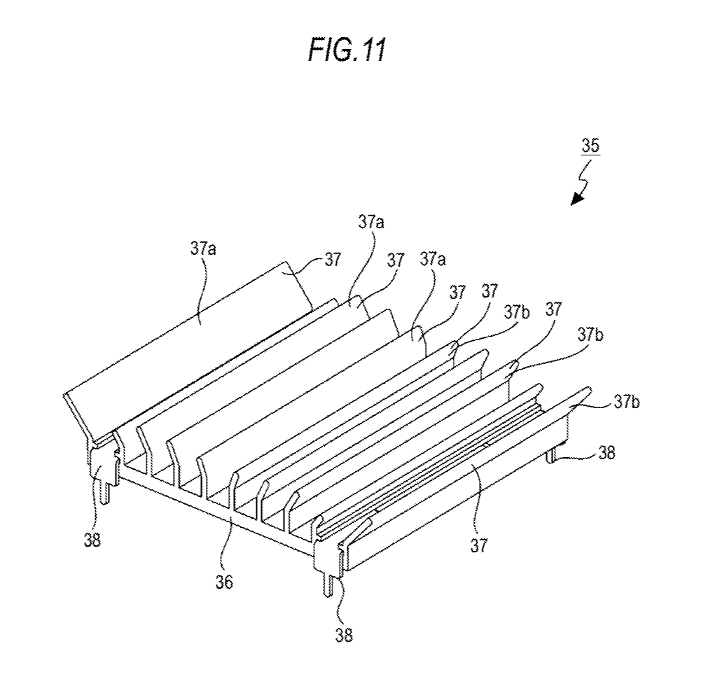

A heat sink 35 is attached on an approximately central portion of the circuit substrate 31. The heat sink 35 is formed by using metal materials having high heat-releasing performance, for example, aluminum, copper, iron or materials obtained by plating iron with tin or copper, including an attachment base 36 facing up and down directions and plural fins 37, 37, . . . protruding upward from the attachment base 36 (see FIG. 2, FIG. 3 and FIG. 11).

The fins 37, 37, . . . are provided apart from one another in the right and left direction at approximately equal intervals, in which end portions at least on the upper side are inclined in respective given directions with respect to the vertical direction. Fins 37a, 37a, . . . positioned on the left side are inclined so as to extend in a diagonally left upward direction, and fins 37b, 37b, . . . positioned on the right side are inclined so as to extend in a diagonally right upward direction by using the center of the attachment base 36 in the right and left direction as a reference.

The fins 37a, 37a, . . . positioned on the left side are formed so that an inclined angle with respect to a vertical direction is increased as going left, and the fins 37b, 37b, . . . positioned on the right side are formed so that the inclined angle with respect to the vertical direction is increased as going right.

Pieces to be attached 38, 38, . . . are attached to four corner positions of the attachment base 36 respectively. As the pieces to be attached 38, 38, . . . are attached to the circuit substrate 31 by soldering and so on, the heat sink 35 is arranged on the circuit substrate 31 in a state where the attachment base 36 is separated upward from an upper surface 31a. Accordingly, part of electronic components 32, 32, . . . to be heat sources are positioned under the attachment base 36 in the state where the heat sink 35 is positioned on the circuit substrate 31.

### [Connection Structure of Outer Casing]

The top surface portion 3 and the case portion 4 are connected in the up and down direction by, for example, adhesion or the like in the state where the top surface portion 3, the case portion 4 and the bottom surface portion 5 are formed as described above (see FIG. 3). In the state where the top surface portion 3 and the case portion 4 are connected, the lower surface 3b of the top surface portion 3 is adhered to the plane portion 22 in the connection surface portion 12 of the case portion 4 by surface contact, thereby positioning the top surface portion 3 with respect to the case portion 4.

A gap is formed between the inclined surface 6 formed at the outer peripheral portion of the top surface portion 3 and the inclined surface 13 formed on the upper edge portion of the outer peripheral surface portion 8 of the case portion 4, which is a heat releasing hole 39 releasing air temperature of which is increased inside the outer casing 2 to the outside. The inclined surface 6 and the inclined surface 13 are respectively inclined so as to be displaced upward as extending outward, and both surfaces are positioned opposite to each other in almost parallel to each other.

The heat releasing hole 39 is connected to space below the fluid guide portions 23, 23, . . . inside the case portion 4 through space inside the protruding portions 15, 15, . . . and the protruding portions 18, 18, . . . provided in the case portion 4 as well as the releasing holes 17a, 17a, . . . and the releasing holes 20a, 20a, . . . respectively formed in the protruding portions 15, 15, . . . and the protruding portions 18, 18, . . . .

The case portion 4 and the bottom surface portion 5 are connected by the locking protrusions 26b, 26b, . . . being locked into the locking concave portions 4a, 4a, . . . and by the connection shaft portions 21, 21, . . . butting against the connection protrusions 30, 30, . . . in the up and down direction and screwing them. In the case where the case portion 4 and the bottom surface portion 5 are connected to each other, the connection shaft portions 21, 21, . . . butt against the connection protrusions 30, 30, . . . in the up and down direction to thereby position the case portion 4 with respect to the bottom surface portion 5.

A gap is formed between the inclined surface 28 formed at the outer peripheral portion of the bottom surface portion 5 and the inclined surface 14 formed on the bottom edge portion of the outer peripheral surface portion 8 of the case portion 4, which is an air inflow hole 40 allowing outside air to flow into the outer casing 2. The inclined surface 28 and the inclined surface 14 are respectively inclined so as to be displaced downward as extending outward, and both surfaces are positioned opposite to each other in almost parallel to each other.

The air inflow hole 40 is connected to an internal space 41 in the outer casing 2 in which the circuit substrate 31 is arranged.

In the state where the case portion 4 and the bottom surface portion 5 are connected, the support wall portion 27 of the bottom surface portion 5 is arranged in the opening 11a between the protruding surface portions 11, 11 of the case portion 4.

The top surface portion 3, the case portion 4 and the bottom surface portion 5 are connected and the circuit substrate 31, the heat sink 35 and the like are arranged inside the outer casing 2 as described above to thereby configure the electronic apparatus 1. In the electronic apparatus 1, the fluid guide portions 23, 23, . . . of the case portion 4 are arranged over the heat sink 35 so as to be opposite to each other, and the first guide surface portions 24, 24, . . . and the second guide surface portions 25, 25, . . . of the fluid guide portions 23, 23, . . . are respectively inclined in directions toward the heat releasing hole 39. The fins 37, 37, . . . of the heat sink 35 are also inclined in directions toward the heat releasing hole 39.

Additionally, the inclined direction of the first guide surface portions 24, 24, . . . on the left side of the fluid guide portions 23, 23, . . . is the same as the inclined direction of the fins 37a, 37a, . . . on the left side of the heat sink 35 positioned just below the first guide surface portions 24, 24, . . . . Similarly, the inclined direction of the second guide surface portions 25, 25, . . . on the right side of the fluid guide portions 23, 23, . . . is the same as the inclined direction of the fins 37b, 37b, . . . on the right side of the heat sink 35 positioned just below the second guide surface portions 25, 25, . . . .

At this time, the inclined surface 6 of the top surface portion 3 and the inclined surface 13 of the case portion 4 are inclined in a direction where the heat sink 35 exists on an extended line in the inclined direction. The inclined surface 28 of the bottom surface portion 5 and the inclined surface 14 of the case portion 4 are also inclined in a direction where the heat sink 35 exists on an extended line in the inclined direction.

The ridge portion 7 provided in the top surface portion 3 and the ridge portion 29 provided in the bottom surface portion 5 are respectively formed just inside the heat releasing hole 39 and the air inflow hole 40. The invasion of dust from the heat releasing hole 39 and the air inflow hole 40 can be respectively suppressed by the ridge portion 7 and the ridge portion 29.

### [Heat Release Operation]

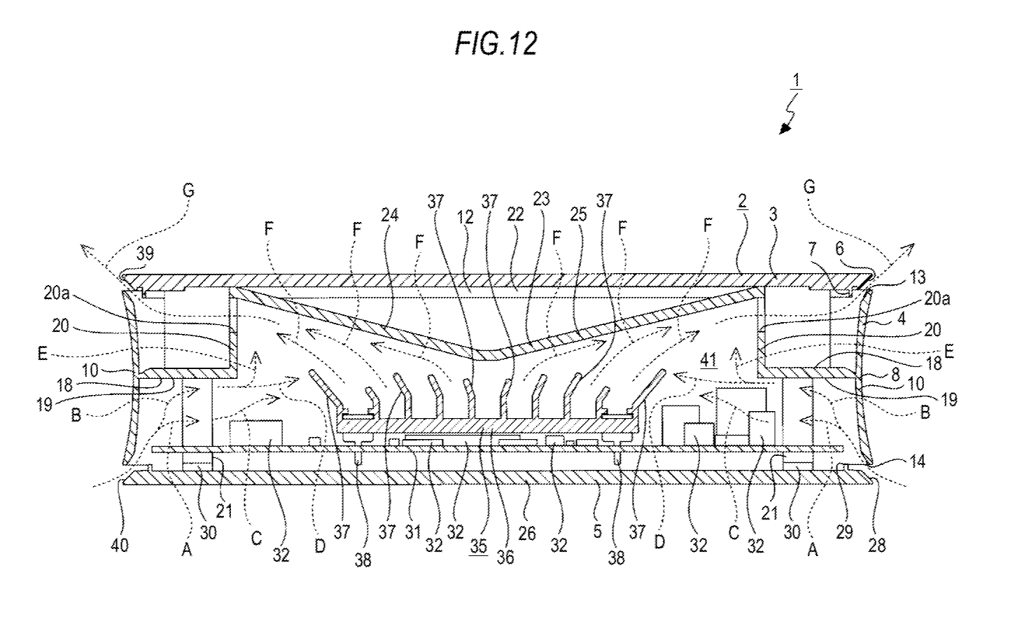

In the electronic apparatus 1 configured as the above, the electronic components 32, 32, . . . generate heat when the electronic components 32, 32, . . . mounted on the circuit substrate 31 are driven. When the electronic components 32, 32, . . . generate heat, the temperature of air existing in the internal space 41 in the outer casing 2 is increased and convection occurs (see FIG. 12).

When convection occurs in the internal space 41, the outside air is taken into the internal space 41 from the air inflow hole 40 formed between the base portion 4 and the bottom surface portion 5 (see arrows A and B). Part of the air taken into the internal space 41 flows toward the heat sink 35 by being guided by the first guide wall portions 16, 16, . . . of the protruding portions 15, 15, . . . and the first guide wall portions 19, 19, . . . of the protruding portions 18, 18, . . . (see arrows C and D). Another part of the air taken into the internal space 41 flows upward by being guided by the second guide wall portions 17, 17, . . . of the protruding portions 15, 15, . . . and the second guide wall portions 20, 20, . . . of the protruding portions 18, 18, . . . (see arrows E).

At this time, the heat chiefly generated in the electronic components 32, 32, . . . arranged below the attachment base 36 of the heat sink 35 is transmitted to the heat sink 35 and released from the attachment base 36 and the fins 37, 37, . . . .

The air temperature of which has been increased due to heat released from the fins 37, 37, . . . of the heat sink 35 flows toward the heat releasing hole 39 as the fins 37, 37, . . . are respectively inclined in directions toward the heat releasing hole 39 (see arrows F). The air temperature of which has been increased in the internal space 41 flows toward the heat releasing hole 39 by being guided by the first guide surface portions 24, 24, . . . and the second guide surface portions 25, 25, . . . as the first guide surface portions 24, 24, . . . and the second guide surface portions 25, 25, . . . of the fluid guide portions 23, 23, . . . are respectively inclined in directions toward the heat releasing hole 39 (see arrows F).

As described above, the air temperature of which has been increased in the internal space 41 flows toward the heat releasing hole 39 along the inclined directions of the fins 37, 37, . . . and the inclined directions of the first guide surface portions 24, 24, . . . and the second guide surface portions 25, 25, . . . , and is released from the heat releasing hole 39 to the outside through the releasing holes 17a, 17a, . . . and the releasing hole 20a, 20a, . . . (see arrows G).

### [Brief]

As described above, the fluid guide portions 23, 23, . . . are inclined in directions toward the heat releasing hole 39, and the fins 37, 37, . . . of the heat sink 35 are inclined in directions toward the heat releasing hole 39 in the electronic apparatus 1.

Therefore, the heat released from the heat sink 35 can be effectively released from the outer casing 2 to the outside without using a member for forcibly generating convection such as a cooling fan, and heat release efficiency can be improved without increasing manufacturing costs.

As the heat releasing hole 39 is formed between the outer peripheral surface portion 8 of the case portion 4 and the top surface portion 3 in the electronic apparatus 1, for example, it is not necessary to form plural heat releasing holes in the top surface portion 3 or the case portion 4, as a result, the amount of releasing air from the inside of the outer casing 2 is increased to thereby increase the heat-releasing performance while securing simplification of structures of the top surface portion 3 and the case portion 4.

As the air inflow hole 40 is formed between the outer peripheral surface portion 8 of the case portion 4 and the bottom surface portion 5 in the electronic apparatus 1, for example, it is not necessary to form plural air inflow holes in the bottom surface portion 5 or the case portion 4, as a result, the amount of taking air inside the outer casing is increased to thereby increase the heat-releasing performance while securing simplification of structures of the bottom surface portion 5 and the case portion 4.

As the heat releasing hole is formed between the top surface portion 3 and the case portion 4, and the air inflow hole is formed between the bottom surface portion 5 and the case portion 4, the heat releasing hole and the air inflow hole are not conspicuous from the outside and designability of the electronic apparatus 1 can be improved.

As the air inflow hole 40 is formed between the outer peripheral surface portion 8 of the case portion 4 and the bottom surface portion 5 in the electronic apparatus 1, for example, it is not necessary to form plural air inflow holes in the bottom surface portion 5 and the case portion 4, as a result, the amount of taking air inside the outer casing is increased to thereby increase the heat-releasing performance while securing simplification of structures of the bottom surface portion 5 and the case portion 4.

Moreover, as the heat releasing hole 39 is formed in circumference between the outer peripheral surface portion 8 of the case portion 4 and the top surface portion 3 in the electronic apparatus 1, the amount of releasing air from the inside of the outer casing 2 is increased to thereby improve the heat release efficiency.

As the air inflow hole 40 is formed in circumference between the outer peripheral surface portion 8 of the case portion 4 and the bottom surface portion 5 in the electronic apparatus 1, the amount of taking air inside the outer casing 2 is increased to thereby improve the heat release efficiency.

Furthermore, as the inclined surface 6 is formed at the outer peripheral portion of the top surface portion 3 and the inclined surface 13 of the case portion 4 is formed at a position opposite to the inclined surface 6, the air temperature of which is increased inside the outer casing 2 and flows upward along the inclines surface 6 and the inclined surface 13 smoothly, which increases flowability of air to be released to the outside and improves the heat release efficiency.

Additionally, as the inclined surface 28 is formed at the outer peripheral portion of the bottom surface portion 5 and the inclined surface 14 of the case portion 4 is formed at a position opposite to the inclined surface 28, the air flows upward toward the inside of the outer casing 2 flows along the inclined surface 28 and the inclined surface 14 smoothly, which increases flowability of air flowing into the outer casing 2 and improves the heat release efficiency.

The outer casing 2 is also provided with the first guide wall portions 16, 16, . . . as well as 19, 19, . . . which guide the air flowing from the air inflow hole 40 in the direction toward the heat sink 35, therefore, the amount of air flowing toward the heat sink 35 is increased and the heat release efficiency can be further improved.

As the first guide wall portions 16, 16, . . . as well as 19, 19, . . . are continuously provided on the inner surface of the outer peripheral surface portion 8 as part of the protruding portions 15, 15, . . . as well as 18, 18, . . . , not only the heat release efficiency can be improved but also the case portion 4 is reinforced and the stiffness of the case portion 4 can be increased.

The inclined angle of plural fins 37, 37, . . . of the heat sink 35 is increased as coming close to the outer peripheral surface portion 8 by using the center of the attachment base 36 as a reference.

Accordingly, intervals of the fins 37, 37, . . . become wider as the fins draw away from the attachment base 36, which increases flowability of air with increased temperature between the fins 37, 37, . . . and improves the heat release efficiency.

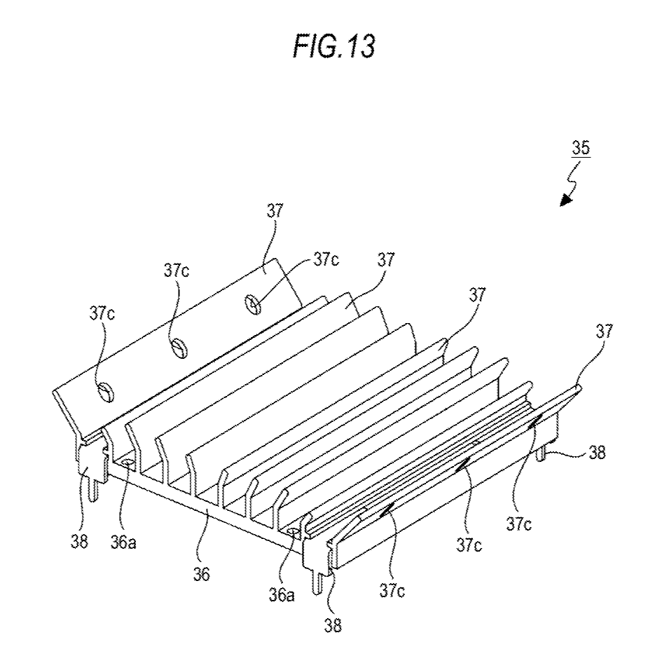

In the heat sink 35, air flow holes 37c, 37c, . . . for allowing the air with increased temperature to flow may be formed in at least one of the fins 37, 37, . . . (see FIG. 13). When the air flow holes 37c, 37c, . . . are formed in the fin 37, the flowability of air with increased temperature can be further increased between the fins 37, 37, . . . and the heat release efficiency can be further improved.

It is also possible to form air flow holes 36a, 36a, . . . allowing the air with increased temperature to flow in the attachment base 36 of the heat sink 35. When the air flow holes 36a, 36a, . . . are formed in the attachment base 36, the flowability of the air with increased temperature can be further increased between the fins 37, 37, . . . and the heat release efficiency can be further improved.

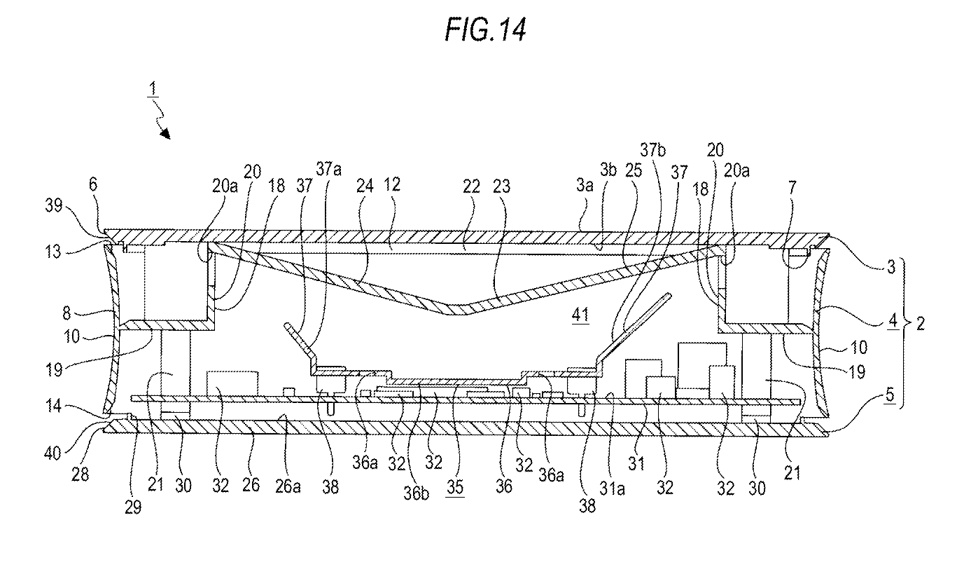

The number of fins 37 of the heat sink 35 is optional, and, for example, two fins 37, 37 protruding from both end portions of the attachment base 36 can be provided as shown in FIG. 14. In this case, it is also preferable to form the air flow holes 36a, 36a, . . . allowing the air with increased temperature to flow in the attachment base 36. When the air flow holes 36a, 36a, . . . are formed in the attachment base 36, the heat release efficiency can be improved. The heat sink 35 shown in FIG. 14 is provided with a protruding surface portion 36b protruding downward at the center of the attachment base 36, and the protruding surface portion 36b is positioned close to the electronic components 32 having a high heat generation amount at the time of driving. Accordingly, transmission efficiency of the heat generated in the electronic components 32 with respect to the heat sink 35 is high, which can further improve the heat release efficiency.

### [Measurement Data]

Measurement results performed concerning heat release effects of the heat sink 35 and the fluid guide portions 23 will be explained below. All measurement results shown below were obtained by measuring temperatures at respective portions at the time of driving the electronic components 32, 32, under environment of 27° C. The measurement of temperatures was performed at the center of the top surface portion 3 of the outer casing 2 and the center of the electronic component 32 positioned under the heat sink 35 and performing signal processing.

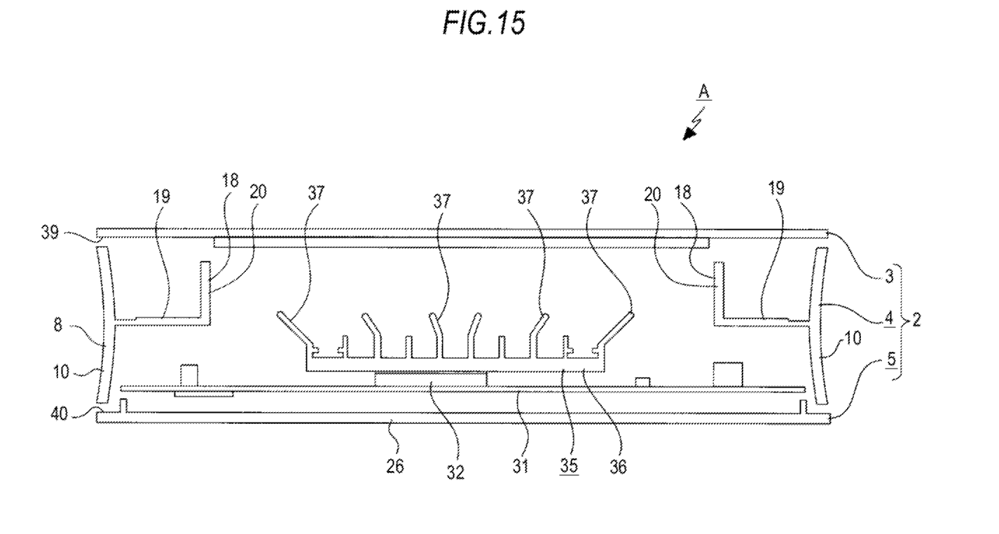

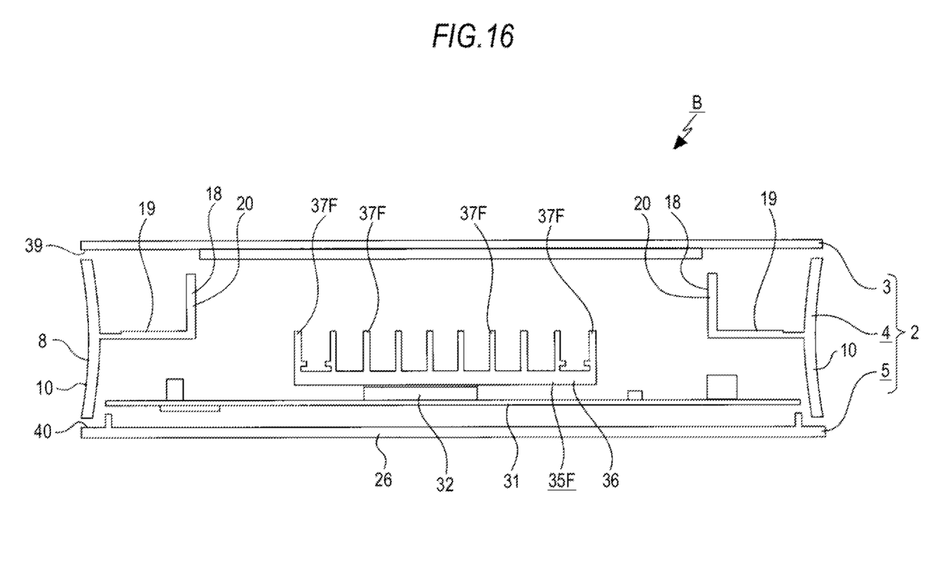

First, measurement was performed with respect to an electronic apparatus A (see FIG. 15) provided with the heat sink 35 having the fins 37, 37, . . . inclined with respect to the vertical direction and an electronic apparatus B (see FIG. 16) provided with a heat sink 35F having fins 37F, 37F, . . . extending in the vertical direction and not being inclined, in the case where the fluid guide portions 23 were not provided.

In the electronic apparatus A, a surface temperature at the center of the top surface portion 3 of the outer casing 2 was 45.1° C. and a surface temperature at the center of the electronic component 32 was 76.6° C.

In the electronic apparatus B, a surface temperature at the center of the top surface portion 3 of the outer casing 2 was 45.3° C. and a surface temperature at the center of the electronic component 32 was 78.2° C.

When comparing the electronic apparatus A with the electronic apparatus B, the electronic apparatus A had a lower value by 1.6° C. in the surface temperature at the center of the electronic apparatus 32, therefore, a result indicating improvement of the heat release efficiency by using the heat sink 35 was obtained.

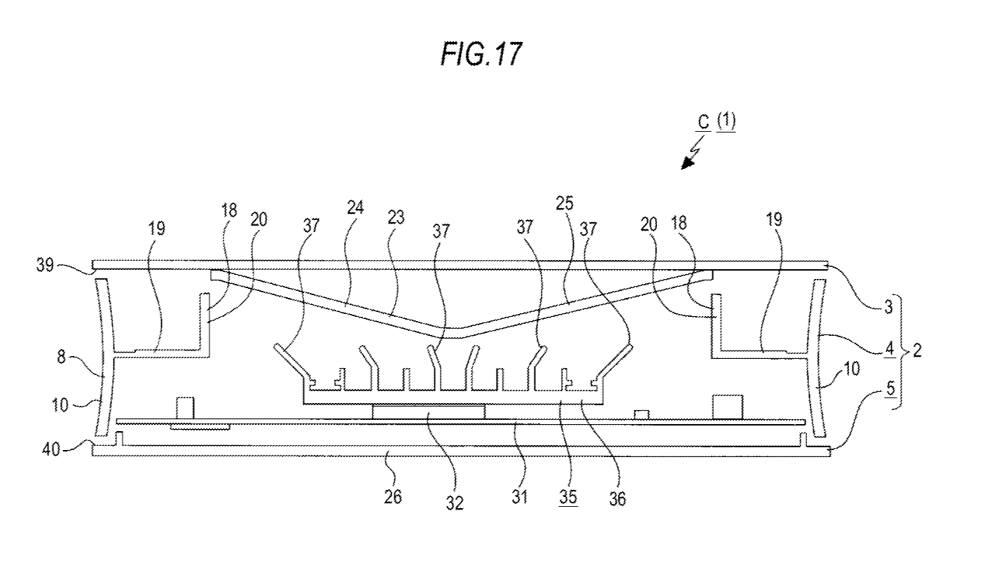

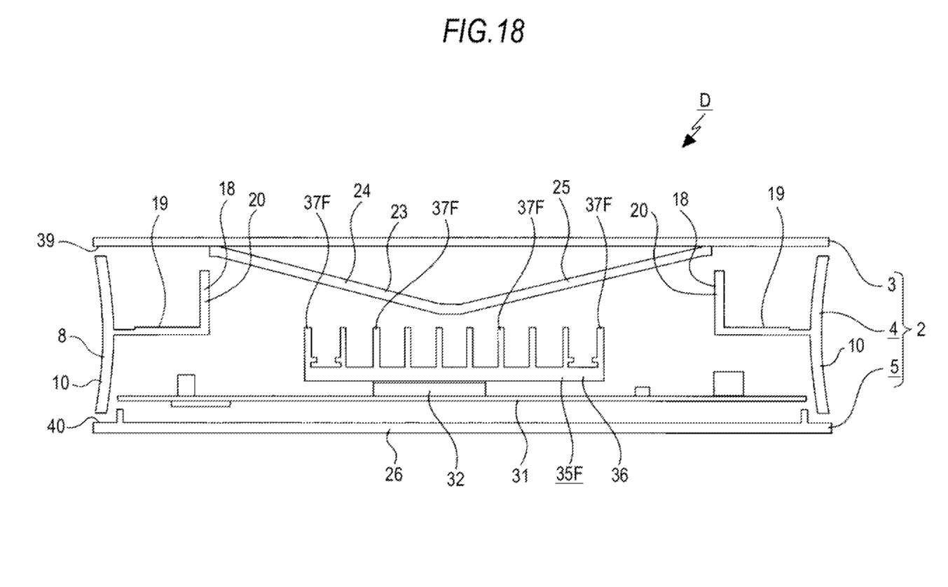

Next, measurement was performed with respect to an electronic apparatus C (see FIG. 17) provided with the heat sink 35 having the fins 37, 37, . . . inclined with respect to the vertical direction and an electronic apparatus D (see FIG. 18) provided with the heat sink 35F having fins 37F, 37F, . . . extending in the vertical direction and not being inclined, in the case where the fluid guide portions 23 were provided. The electronic apparatus C corresponds to the electronic apparatus 1 according to the embodiment of the present disclosure.

In the electronic apparatus C, a surface temperature at the center of the top surface portion 3 of the outer casing 2 was 40.0° C. and a surface temperature at the center of the electronic component 32 was 74.9° C.

In the electronic apparatus D, a surface temperature at the center of the top surface portion 3 of the outer casing 2 was 40.4° C. and a surface temperature at the center of the electronic component 32 was 76.2° C.

When comparing the electronic apparatus C (electronic apparatus 1) with the electronic apparatus D, the electronic apparatus C had a lower value by 1.3° C. in the surface temperature at the center of the electronic apparatus 32, therefore, a result indicating improvement of the heat release efficiency by using the heat sink 35 was obtained.

When comparing the electronic apparatus A with the electronic apparatus C (electronic apparatus 1), the electronic apparatus C had a lower value by 5.1° C. in the surface temperature at the center of the top surface portion 3, and the electronic apparatus C had a lower value by 1.7° C. in the surface temperature at the center of the electronic apparatus 32. Furthermore, when comparing the electronic apparatus B with the electronic apparatus D, the electronic apparatus D had a lower value by 4.9° C. in the surface temperature at the center of the top surface portion 3, and the electronic apparatus D had a lower value by 2.0° C. in the surface temperature at the center of the electronic apparatus 32.

Consequently, the results indicating improvement of the heat release efficiency by providing the fluid guide portions 23 were obtained.

According to the above measurement results, it was found that the heat release efficiency can be improved by using the heat sink 35 and that the heat release efficiency can be improved also by providing the fluid guide portions 23. Therefore, in the electronic apparatus 1 having the heat sink 35 and the fluid guide portions 23, it was proved that the heat release efficiency is drastically improved in a synergistic manner by providing the heat sink 35 and the fluid guide portions 23 in the electronic apparatus 1 having the heat sink 35 and the fluid guide portions 23.

### [Present Disclosure]

The present disclosure may be implemented as the following configurations.

(1) An electronic apparatus including

an outer casing in which an air inflow hole allowing outside air to flow into internal space and a heat releasing hole releasing air temperature of which has been increased in the internal space to the outside are formed,

a circuit substrate arranged in the internal space of the outer casing and on which electronic components to be heat sources at the time of driving are mounted, and

a heat sink having an attachment base attached to the circuit substrate and plural fins protruding from the attachment base,

in which the outer casing is provided with fluid guide portions positioned opposite to the plural fins of the heat sink and guiding the air with increased temperature,

the fluid guide portions are inclined in directions toward the heat releasing hole and

the plural fins are inclined to directions toward the heat releasing hole.

(2) The electronic apparatus described in the above (1),

in which the outer casing includes a case portion having an outer peripheral surface portion, a top surface portion attached to the outer peripheral surface portion from one opening side of the outer peripheral surface portion and a bottom surface portion attached to the outer peripheral surface portion from the other opening side of the outer peripheral surface portion, and

a gap is formed between the outer peripheral surface portion and the top surface portion, which is used as the heat releasing hole.

(3) The electronic apparatus described in the above (1) or (2),

in which the outer casing includes a case portion having an outer peripheral surface portion, a top surface portion attached to the outer peripheral surface portion from one opening side of the outer peripheral surface portion and a bottom surface portion attached to the outer peripheral surface portion from the other opening side of the outer peripheral surface portion, and

a gap is formed between the outer peripheral surface portion and the bottom surface portion, which is used as the air inflow hole.

(4) The electronic apparatus described in the above (2) or (3),

in which the heat releasing hole is formed in circumference between the outer peripheral surface portion and the top surface portion.

(5) The electronic apparatus described in any one of the above (2) to (4),

in which the air inflow hole is formed in circumference between the outer peripheral surface portion and the bottom surface portion.

(6) The electronic apparatus described in any one of the above (2) to (5),

in which a surface in an outer peripheral portion of the top surface portion positioned opposite to the outer peripheral surface portion is formed as an inclined surface to be apart from the bottom surface portion as extending to an outer periphery.

(7) The electronic apparatus described in any one of the above (2) to (6),

in which a surface of the outer peripheral surface portion opposite to the top surface portion is formed as an inclined surface inclined in a direction along the inclined surface of the top surface portion.

(8) The electronic apparatus described in any one of the above (2) to (7),

in which a surface in an outer peripheral portion of the bottom surface portion positioned opposite to the outer peripheral surface portion is formed as an inclined surface to be apart from the top surface portion as extending an outer periphery.

(9) The electronic apparatus described in any one of the above (2) to (8),

in which a surface of the outer peripheral surface portion opposite to the bottom surface portion is formed as an inclined surface inclined in a direction along the inclined surface of the bottom surface portion.

(10) The electronic apparatus described in any one of the above (1) to (9),

in which the outer casing is provided with guide wall portions guiding air flowing from the air inflow hole to directions toward the heat sink.

(11) The electronic apparatus described in the above (10),

in which the outer casing has a case portion having an outer peripheral surface portion, a top surface portion attached to the outer peripheral surface portion from one opening side of the outer peripheral surface portion and a bottom surface portion attached to the outer peripheral surface portion from the other opening side of the outer peripheral surface portion, and

the outer casing is provided with protruding portions having the guide wall portions and protruding from an inner surface of the outer peripheral surface portion.

(12) The electronic apparatus described in any one of the above (1) to (11),

in which an inclined angle of the plural fins of the heat sink is increased as coming close to the outer peripheral surface portion by using the center of the attachment base as a reference.

(13) The electronic apparatus described in any one of the above (1) to (12),

in which air flow holes allowing the air with increased temperature to flow are formed in at least one of the plural fins of the heat sink.

(14) The electronic apparatus described in any one of the above (1) to (13),

in which air flow holes allowing the air with increased temperature to flow are formed in the attachment base of the heat sink.

Specific shapes and structures of respective portions shown in the above preferred embodiment of the present disclosure are just examples in embodying the present disclosure, and the technical scope of the present disclosure should not be limitedly interpreted by these examples.

It should be understood by those skilled in the art that various modifications, combinations, sub-combinations and alterations may occur depending on design requirements and other factors insofar as they are within the scope of the appended claims or the equivalents thereof.

What is claimed is:

1. An electronic apparatus comprising:
an outer casing in which an air inflow hole allowing outside air to flow into internal space and a heat releasing hole releasing air temperature of which has been increased in the internal space to the outside are formed;
a circuit substrate arranged in the internal space of the outer casing and on which electronic components to be heat sources at the time of driving are mounted; and
a heat sink having an attachment base attached to the circuit substrate and plural fins protruding from the attachment base,
wherein the outer casing is provided with fluid guide portions positioned opposite to the plural fins of the heat sink and guiding the air with increased temperature,
the fluid guide portions are inclined in directions toward the heat releasing hole and
the plural fins are inclined to directions toward the heat releasing hole.

2. The electronic apparatus according to claim 1,
wherein the outer casing includes a case portion having an outer peripheral surface portion, a top surface portion attached to the outer peripheral surface portion from one opening side of the outer peripheral surface portion and a bottom surface portion attached to the outer peripheral surface portion from the other opening side of the outer peripheral surface portion, and
a gap is formed between the outer peripheral surface portion and the top surface portion, which is used as the heat releasing hole.

3. The electronic apparatus according to claim 1,
wherein the outer casing includes a case portion having an outer peripheral surface portion, a top surface portion attached to the outer peripheral surface portion from one opening side of the outer peripheral surface portion and a bottom surface portion attached to the outer peripheral surface portion from the other opening side of the outer peripheral surface portion, and
a gap is formed between the outer peripheral surface portion and the bottom surface portion, which is used as the air inflow hole.

4. The electronic apparatus according to claim 2,
wherein the heat releasing hole is formed in circumference between the outer peripheral surface portion and the top surface portion.

5. The electronic apparatus according to claim 4,
wherein the air inflow hole is formed in circumference between the outer peripheral surface portion and the bottom surface portion.

6. The electronic apparatus according to claim 2,
wherein a surface in an outer peripheral portion of the top surface portion positioned opposite to the outer peripheral surface portion is formed as an inclined surface to be apart from the bottom surface portion as extending to an outer periphery.

7. The electronic apparatus according to claim 6,
wherein a surface of the outer peripheral surface portion opposite to the top surface portion is formed as an inclined surface inclined in a direction along the inclined surface of the top surface portion.

8. The electronic apparatus according to claim 3,
wherein a surface in an outer peripheral portion of the bottom surface portion positioned opposite to the outer peripheral surface portion is formed as an inclined surface to be apart from the top surface portion as extending to an outer periphery.

9. The electronic apparatus according to claim 8,
wherein a surface of the outer peripheral surface portion opposite to the bottom surface portion is formed as an inclined surface inclined in a direction along the inclined surface of the bottom surface portion.

10. The electronic apparatus according to claim 1,
wherein the outer casing is provided with guide wall portions guiding air flowing from the air inflow hole to directions toward the heat sink.

11. The electronic apparatus according to claim 10,
wherein the outer casing has a case portion having an outer peripheral surface portion, a top surface portion attached to the outer peripheral surface portion from one opening side of the outer peripheral surface portion and a bottom surface portion attached to the outer peripheral surface portion from the other opening side of the outer peripheral surface portion, and
the outer casing is provided with protruding portions having the guide wall portions and protruding from an inner surface of the outer peripheral surface portion.

12. The electronic apparatus according to claim 1,
wherein an inclined angle of the plural fins of the heat sink is increased as coming close to the outer peripheral surface portion by using the center of the attachment base as a reference.

13. The electronic apparatus according to claim 1,
wherein air flow holes allowing the air with increased temperature to flow are formed in at least one of the plural fins of the heat sink.

14. The electronic apparatus according to claim 1,
wherein air flow holes allowing the air with increased temperature to flow are formed in the attachment base of the heat sink.
